(19) United States
(12) Patent Application Publication
(10) Pub. No.: US 2021/0371997 A1
(43) Pub. Date: Dec. 2, 2021

(54) SURFACE TREATED COPPER FOIL AND COPPER-CLAD LAMINATE

(71) Applicant: Circuit Foil Luxembourg, Sarl, Wiltz (LU)

(72) Inventors: Thomas DEVAHIF, Wiltz (LU); Michel STREEL, Wiltz (LU); Zainhia KAIDI, Wiltz (LU)

(73) Assignee: Circuit Foil Luxembourg, Sarl, Wiltz (LU)

(21) Appl. No.: 16/320,255

(22) PCT Filed: Jul. 31, 2017
(86) PCT No.: PCT/EP2017/069315

§ 371 Date: Jan. 24, 2019

(51) Int. Cl. C25D 1/04; C25D 3/38; B32B 15/20; B32B 15/08; B32B 27/28; H05K 1/05

(52) U.S. Cl. CPC C25D 1/04; C25D 3/38; B32B 15/20; B32B 15/08; H05K 2201/0358; H05K 1/056; B32B 2457/08; H05K 2201/0355; B32B 27/285

(57) ABSTRACT

Disclosed herein relates to a copper foil having a low roughness property by roughening a matte side, wherein a thickness of the copper foil is from 5 μm to 70 μm, and profilometer-measured mean roughness of the roughened surface of the copper foil is from 0.5 μm to 2.0 μm, and wherein profilometer-measured mean roughness Rz JIS of the roughened matte side of the copper foil is lower than that of a shiny side of the copper foil. The copper foil provided in the present invention has excellent adhesion with a resin and an electrical property while having low roughness through surface roughening.

### BACKGROUND OF THE INVENTION

### Field of the Invention

Exemplary embodiments of the present invention relate to a surface treated copper foil and a copper-clad laminate including the same, and in particular, to a copper foil having excellent adhesion strength while having very low roughness of the matte side through surface roughening, and a copper-clad laminate and a printed circuit board including the same.

### Description of the Related Art

Printed wiring boards have made significant advances over the past half-century, and are currently used in almost all electronic devices. With a recent increase in the demands for miniaturization and higher performance of electronic devices, high density installation of loaded components or higher frequency of signals has made a progress, and excellent high frequency response for printed wiring boards has been required.

As for boards for a high frequency, a decrease in the transmission loss has been required in order to secure output signal qualities. Transmission loss is mostly formed with dielectric loss caused by a resin (board side) and conductor loss caused by a conductor (copper foil side). Dielectric loss decreases as a dielectric constant of a resin and a dissipation factor decrease. In a high frequency signal, conductor loss is mainly caused by a decrease in a cross-sectional area in which a current flows by a skin effect, that is, a current flows only on a surface of a conductor as a frequency increases, and an increase in the resistance.

Meanwhile, a copper foil or a copper alloy foil (hereinafter, referred to simply as “copper foil”) is widely used for the purpose of a conductor (conductive member or conductive strip). A printed circuit board is manufactured by layering (laminating) a copper foil on a polyphenylene ether (PPE) film or by coating a copper foil with a varnish mainly composed of polyphenylene ether (PPE). Hereinafter, materials such as polyphenylene ether (PPE) film, varnish, or solidified varnish to be used for the printed circuit board are referred as “base material (substrate) for a printed circuit board” or simply as “base material”.

A good adhesion is required between the copper foil and the base material for a printed circuit board. Therefore, the roughening treatment is frequently conducted for a surface of the copper foil to increase an anchoring effect, thereby improving the adhesion strength with the base material for a printed circuit board.

The copper foil is classified into an electro-deposited copper foil and a rolled copper foil according to the manufacturing method therefor. However, the roughening treatment is conducted in similar manner for these two types of copper foils.

For example, as a manner of roughening treatment, a manner of applying (depositing) copper in the form of grains on a surface of the copper foil by burnt plating and a manner of selectively etching grain boundaries by using acid are generally used.

As described above, the roughening process can improve the adhesion strength between the copper foil and the base material by providing an anchoring effect.

In this case, however, the electrical property of the copper foil becomes worse as the roughness increases. Accordingly, the copper foil having both high adhesion strength and superior electrical properties has been demanded.

### SUMMARY OF THE INVENTION

An object of the present invention is to provide a copper foil having excellent adhesion strength with a resin and an excellent electrical property while having very low roughness of the matte side through surface roughening.

Another object of the present invention is to provide a copper-clad laminate, a printed circuit board and an electronic device having, by including the copper foil, excellent adhesion strength with a resin laminated thereon and an excellent electrical property.

However, objects of the present invention are not limited to the objects described above, and other objects that are not mentioned will be clearly understood to those skilled in the art from the descriptions provided below.

One aspect of the present invention relates to a copper foil having a low roughness property by roughening a matte side of the copper foil, wherein a thickness of the copper foil may be from 5 μm to 70 μm, and profilometer-measured mean roughness Rz JIS of the roughened surface of the copper foil may be from 0.5 μm to 2.0 μm, wherein profilometer-measured mean roughness Rz JIS of the roughened matte side of the copper foil is lower than that of a shiny side of the copper foil.

In the present invention, a thickness of the copper foil may be from 5 μm to 15 μm, and profilometer-measured mean roughness Rz JIS of the roughened matte side of the copper foil may be from 0.8 μm to 1.5 μm.

In the present invention, a thickness of the copper foil may be greater than 15 μm and less than or equal to 30 μm, and profilometer-measured mean roughness Rz JIS of the roughened matte side of the copper foil may be from 0.8 μm to 1.1 μm.

In the present invention, a thickness of the copper foil may be greater than 30 μm and less than or equal to 70 μm, and profilometer-measured mean roughness Rz JIS of the roughened matte side of the copper foil may be from 0.7 μm to 1.0 μm.

In the present invention, profilometer-measured maximum roughness Rz JIS of the roughened matte side of the copper foil may be from 1.0 μm to 2.0 μm.

In the present invention, a ratio of the profilometer-measured mean roughness of the shiny side with respect to that of the roughened matte side is greater than 1 and less than or equal to 2.

In the present invention, particle sizes of roughened particles of the roughened matte side of the copper foil may be from 0.1 μm to 2.0 μm.

In the present invention, a height of a projection formed with the roughened particles of the roughened surface of the copper foil may be from 1.0 μm to 5.0 μm.

Another aspect of the present invention relates to a copper-clad laminate including the copper foil according to the present invention; and a resin layer laminated on at least one surface of the copper foil.

Still another aspect of the present invention relates to a printed circuit board including the copper-clad laminate according to the present invention.

Yet another aspect of the present invention relates to an electronic device including the printed circuit board according to the present invention.

It is to be understood that both the foregoing general description and the following detailed description of the present invention are exemplary and explanatory and are intended to provide further explanation of the invention as claimed.

### DESCRIPTION OF SPECIFIC EMBODIMENTS

Hereinafter, preferred embodiments of the present invention will be described. However, the embodiments of the present invention may be modified to various other forms, and the scope of the present invention is not limited to the embodiments described below. In addition, the embodiments of the present invention are provided in order to more completely describe the present invention to those having average knowledge in the art.

After repeated studies, the inventors of the present invention have found out that, in a surface roughened copper foil, adhesion strength of the copper foil and an insulating resin increases and electrical performance is significantly improved as well when controlling a thickness of the copper foil and profilometer-measured mean roughness Rz JIS of the roughened matte side in the copper foil to specific ranges, and have completed the present invention.

One aspect of the present invention relates to a copper foil having a low roughness property by roughening a matte side thereof, wherein a thickness of the copper foil may be from 5 μm to 70 μm, and a profilometer-measured mean roughness Rz JIS of the roughened matte side of the copper foil may be from 0.5 μm to 2.0 μm.

Specific descriptions are as follows.

[Form of Surface Treated Copper Foil and Preparation Method Thereof]

The copper foil used in the present invention may be an electrolytic copper foil or a rolled copper foil and is not particularly limited, but may preferably be an electrolytic copper foil.

In the present invention, a surface of a side on which an electrodeposited copper foil has been contacted with a cathode drum surface is referred to as “shiny side”, and a reverse surface is referred to as “matte side”.

In the present invention, the electrolytic copper foil has a matte side and a shiny side. In the present invention, by roughening the matte side to be adhered to a resin layer or both surfaces including the matte side of the copper foil, adhesion strength with the resin laminated thereon may be enhanced, and heat resistance and the like may be enhanced in addition thereto.

In general, roughening the matte side of the copper foil increases the roughness of the matte side, even the roughness of the matte side becomes greater than that of the shiny side, although before roughening the roughness of the matte side is lower than that of the shiny side.

However, in the present invention, by conducting the roughening process to the matte side of the copper foil under specific conditions, the roughness of the roughened matte side is lower than that of the shiny side, as a result, an insertion loss decreases when the copper foil is applied to make a copper clad laminate.

In the present invention, the roughening process is not particularly limited, and methods known in the art and capable of forming projections on the copper foil surface may be used without limit. However, preferably, a copper foil is introduced to a liquid electrolyte having a temperature comprised between 15 and 30° C. and including copper (Cu) and plating is carried out at specific current density or higher to produce fine nodules (roughened particles) on the copper foil surface.

In addition, the process of capsulating the produced metal nuclei in the present invention may be carried out at a temperature higher than a temperature producing the metal nuclei, and preferably, may be carried out at 45° C. to 60° C., and copper concentration in the liquid electrolyte used may be higher than concentration in the liquid electrolyte producing the metal nuclei.

[Roughened Particles and Projections]

In the present invention, roughened particles are formed on the copper foil surface, preferably the matte side of the copper foil by such a roughening process, and these may form projections.

In the present invention, diameters of the roughened particles may be from 0.1 μm to 2.0 μm.

In addition, in the present invention, a height of the projection formed by the roughened particles may be from 1.0 μm to 5.0 μm. In the present invention, when the height of the projection is less than 1.0 μm, the height is low and sufficient adhesion strength may not be secured, and when the height of the projection is greater than 5.0 μm, projection distribution is not uniform, and the targeted surface roughness range may be difficult to control.

[Surface Roughness of Copper Foil]

In the present invention, through the roughening process as above, mean roughness may be controlled to 0.5 μm to 2.0 μm and maximum roughness to 1.0 μm to 2.0 μm on the roughened surface of the copper foil having a thickness of from 5 μm to 70 μm.

In the present invention, controlling the thickness of the copper foil and profilometer-measured mean roughness Rz JIS, furthermore, maximum roughness of the roughened matte side to specific ranges is preferred since adhesion strength with a resin is enhanced and an electrical property is improved. Especially, in the present invention, by controlling the profilometer-measured mean roughness Rz JIS of the roughened matte side of the copper foil to specific range, the copper foil exhibits a significantly superior the electrical property without diminution of adhesion strength with a resin which is laminated thereon.

In the present invention, when the copper foil has a thickness of from 5 μm to 15 μm, mean roughness Rz JIS of the roughened matte side may be from 0.8 μm to 1.5 μm and preferably from 0.9 μm to 1.3 μm, and maximum roughness Rz JIS of the roughened surface may be from 1.2 μm to 2.0 μm.

In the present invention, when the copper foil has a thickness of greater than 15 μm and less than or equal to 30 μm, mean roughness Rz JIS of the roughened matte side may be from 0.8 μm to 1.1 μm and preferably from 0.85 μm to 1.05 μm, and maximum roughness Rz JIS of the roughened matte side may be from 1.05 μm to 1.6 μm.

In the present invention, when the copper foil has a thickness of greater than 30 μm and less than or equal to 70 μm, mean roughness Rz JIS of the roughened matte side may be from 0.7 μm to 1.0 μm and preferably from 0.74 μm to 1.0 μm, and maximum roughness Rz JIS of the roughened matte side may be from 1.0 μm to 1.5 μm.

In the present invention, a ratio of the mean roughness Rz JIS of the roughened matte side with respect to the mean roughness Rz JIS of the shiny side may be greater than 1 and less than or equal to 2, preferably greater than 1 and less than or equal to 1.9, more preferably, from 1.20 to 1.88.

Herein, when any one of the mean roughness, the maximum roughness and the ratio of the roughness is less than the above-mentioned range, adhesion strength with a resin significantly decreases. In addition, when any one of the mean roughness, the maximum roughness and the ratio of the roughness is greater than the above-mentioned range, an electrical property decreases.

In the present invention, roughness of the roughened surface of the copper foil is measured using a profilometer, and specific equipment is not particularly limited, however, roughness Rz JIS of the roughened surface of the copper foil may be measured in accordance with ISO 4287.

As is apparent from examples and comparative examples to be described below, the surface treated copper foil of the present invention having specific range of surface roughness may have excellent adhesion with a resin laminated thereon.

Another aspect of the present invention relates to a copper-clad laminate including the copper foil according to the present invention; and a resin layer laminated on at least one surface of the copper foil.

In the copper-clad laminate of the present invention, adhesion strength between the copper foil and the resin layer is excellent.

In the present invention, the resin layer may include a non-epoxy-based thermosetting resin composition, and the non-epoxy-based thermosetting resin composition provided in the present invention has properties of overall physical properties including heat resistance and low dielectric properties being excellent by using both a polyphenylene ether resin in which both sides of the molecular chain are modified with unsaturated bond substituents and three or more types of specific cross-linkable curing agents.

The non-epoxy-based thermosetting resin composition in the present invention includes (a) polyphenylene ether having two or more unsaturated substituents selected from the group consisting of vinyl groups and allyl groups on both ends of a molecular chain, or an oligomer thereof; (b) three or more types of cross-linkable curing agents; and (c) a flame retardant. In addition, the thermosetting resin composition may further include an inorganic filler of which surface is treated with a vinyl group-containing silane coupling agent. Herein, a curing accelerator, an initiator (for example, a radical initiator) and the like may be further included as necessary.

(a) Polyphenylene Ether

The thermosetting resin composition according to the present invention includes polyphenylene ether (PPE) or an oligomer thereof. The PPE or the oligomer thereof has two or more vinyl groups, allyl groups or both thereof on both ends of the molecular chain, however, the structure is not particular limited.

In the present invention, allylated polyphenylene ether represented by the following Chemical Formula 1 is preferred: this is due to the fact sides of the compound are modified with two or more vinyl groups, and therefore, the compound is capable of enhancing a glass transition temperature, and satisfying a low coefficient of thermal expansion, a moisture resistance property caused by a decrease in the -OH group, and a dielectric property.

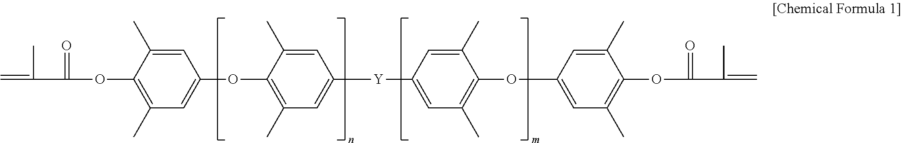

In Chemical Formula 1, Y is one or more types of compounds selected from the group consisting of a bisphenol A-type, a bisphenol F-type, a bisphenol S-type, a naphthalene-type, an anthracene-type, a biphenyl-type, a tetramethyl biphenyl-type, a phenol novolac-type, a cresol novolac-type, a bisphenol A novolac-type and a bisphenol S novolac-type, and m and n are each independently a natural number of 3 to 20.

In the present invention, those having 2 or more vinyl groups on both ends of the molecular chain are normally used, however, those using common unsaturated double bond moieties known in the art besides the vinyl group also belong to the scope of the present invention.

In the present invention, instead using an existing high molecular weight polyphenylene ether (PPE) resin as it is, a form of introducing vinyl groups on both ends of the resin through redistribution is used as a form modified to a low molecular weight through a redistribution reaction using specific bisphenol compounds having increased alkyl group content and aromatic group content. Herein, the redistribution reaction is carried out under the presence of a radical initiator, a catalyst, or both a radical initiator and a catalyst.

Such modified polyphenylene ether has a lower molecular weight compared to existing polyphenylene-derived compounds and has high alkyl group content, and therefore, has excellent compatibility with existing epoxy resins and the like, and processibility is improved since flowability increases when manufacturing a laminate, and a dielectric property is additionally improved. Accordingly, a printed circuit board manufactured using the resin composition of the present invention has an advantage of enhancing physical properties such as moldability, machinability, a dielectric property, heat resistance and adhesion strength.

The polyphenylene ether resin (a) may be obtained by modifying a high molecular weight polyphenylene ether resin having a number average molecular weight range of 10,000 to 30,000 to a low molecular weight having a number average molecular weight (Mn) range of 1,000 to 10,000 through a redistribution reaction under the presence of a bisphenol series compound (except Bisphenol A), and the number average molecular weight (Mn) may be preferably in a 1,000 to 5,000 range, and more preferably in a 1,000 to 3,000 range.

In addition, molecular weight distribution of the polyphenylene ether is suitably 3 or less (Mw/Mn<3), and preferably in a range of 1.5 to 2.5.

In the thermosetting resin composition according to the present invention, the content of the polyphenylene ether resin or the oligomer thereof may be approximately from 20% by weight to 50% by weight based on the total weight of the resin composition.

(b) Cross-Linkable Curing Agent

The thermosetting resin composition according to the present invention includes three or more types of different cross-linkable curing agents.

The cross-linkable curing agent may be selected from the group consisting of a hydrocarbon-based cross-linking agent (b1), a cross-linking agent containing three or more functional groups (b2) and block-structured rubber (b3).

In the present invention, the usable hydrocarbon-based cross-linking agent is not particularly limited as long as it is a hydrocarbon-based cross-linking agent having double bonds or triple bonds, and preferably, may be a diene-based cross-linking agent. Specific examples thereof may include butadiene (for example, 1,2-butadiene, 1,3-butadiene and the like) or polymers thereof, decadiene (for example, 1,9-decadiene and the like) or polymers thereof, octadiene (for example, 1,7-octadiene and the like) or polymers thereof, vinyl carbazole, and the like, and these may be used either alone or as a mixture of two or more types.

The hydrocarbon-based cross-linking agent may have a molecular weight (Mw) range of 500 to 3,000, and preferably, may have a range of 1,000 to 3,000.

In the present invention, nonlimiting examples of the usable cross-linking agent containing three or more (preferably 3 to 4) functional groups may include triallyl isocyanurate (TAIL), 1,2,4-trivinyl cyclohexane (TVCH) and the like, and these may be used either alone or as a mixture of two or more types.

In the present invention, the usable block-structured rubber has a block copolymer form, and may preferably be block copolymer-type rubber containing a butadiene unit, and more preferably, block copolymer-type rubber containing units such as a styrene unit, an acrylonitrile unit and an acrylate unit together with the butadiene unit. Nonlimiting examples thereof may include styrene-butadiene rubber (SBR), acrylonitrile-butadiene rubber, acrylate-butadiene rubber, acrylonitrile-butadiene-styrene rubber and the like, and these may be used either alone or as a mixture of two or more types.

In the present invention, the content of the cross-linkable curing agent (b) in the thermosetting resin composition is not particiularly limited, but may be in a range of approximately 5% by weight to 45% by weight based on the total weight of the resin composition, and preferably, may be in a range of approximately 10% by weight to 30% by weight. When the content of the cross-linkable curing agent is within the range described above, a low dielectric property, curability, molding machinability and adhesion strength of the resin composition are favorable.

According to one example, when mixing the hydrocarbon-based cross-linking agent (b1), the cross-linking agent containing three or more functional groups (b2) and the block-structured rubber as the three or more types of cross-linkable curing agents, each content of the hydrocarbon-based cross-linking agent (b1), the cross-linking agent containing three or more functional groups (b2) and the block-structured rubber (b3) is in an approximately 1.65% by weight to 15% by weight range, preferably in an approximately 3.33% by weight to 10% by weight range, and more preferably in an approximately 5% by weight to 10% by weight range, based on the total weight of the resin composition.

According to another example, when mixing the hydrocarbon-based cross-linking agent (b1), the cross-linking agent containing three or more functional groups (b2) and the block-structured rubber as the three or more types of cross-linkable curing agents, the ratio of the hydrocarbon-based cross-linking agent (b1), the cross-linking agent containing three or more functional groups (b2) and the block-structured rubber (b3) used is a weight ratio of b1:b2:b3=1 to 20:1 to 20:1, and preferably a weight ratio of b1:b2:b3=1 to 7:1 to 7:1.

As necessary, in the present invention, common cross-linkable curing agents known in the art may be further included in addition to the hydrocarbon-based curing agent, the cross-linking agent containing three or more functional groups and the block-structured rubber described above. Herein, the cross-linkable curing agent preferably has excellent miscibility with polyphenylene ether of which sides are modified with vinyl groups, allyl groups and the like.

(c) Flame Retardant

In the present invention, the thermosetting resin composition may include a flame retardant (c).

As the flame retardant, common flame retardants known in the art may be used without limit, and as one example, halogen flame retardants containing bromine or chlorine; phosphorous flame retardants such as triphenyl phosphate, tricresyl phosphate, trisdichloropropylphosphate and phosphazene; antimony-based flame retardants such as antimony trioxide; inorganic flame retardants such as metal hydroxides such as aluminum hydroxide and magnesium hydroxide may be included. In the present invention, an addition-type bromine flame retardant that is not reactive with polyphenylene ether and does not decline a heat resisting property and a dielectric property is suitable.

In the thermosetting resin composition of the present invention, the flame retardant may be included in approximately 10% by weight to 30% by weight based on the total weight of the resin composition, and preferably, may be included in an approximately 10% by weight to 20% by weight range. When the flame retardant is included in the above-mentioned range, sufficient flame resistance of a flame resistance 94V-0 level may be obtained, and excellent heat resistance and electrical properties may be obtained.

(d) Inorganic Filler of which Surface is Treated with Vinyl Group-Containing Silane Coupling Agent

The thermosetting resin composition according to the present invention may further include an inorganic filler of which surface is treated with a vinyl group-containing silane coupling agent.

In the present invention, the usable inorganic filler (d) is not particularly limited as long as it is an inorganic filler known in the art and its surface is treated with a vinyl group-containing silane coupling agent. Examples thereof may include silicas such as natural silica, fused silica, amorphous silica and crystalline silica; boehmite, alumina, talc, spherical glass, calcium carbonate, magnesium carbonate, magnesia, clay, calcium silicate, titanium oxide, antimony oxide, glass fiber, aluminum borate, barium titanate, strontium titanate, calcium titanate, magnesium titanate, bismuth titanate, titanium oxide, barium zirconate, calcium zirconate, boron nitride, silicon nitride, mica and the like, and surfaces thereof are treated with a vinyl group-containing silane coupling agent. Such an inorganic filler may be used either alone or as a mixture of two or more. Among these, fused silica exhibiting a low coefficient of thermal expansion is preferred.

In addition, the content of the inorganic filler is not particularly limited, and may be properly controlled considering a bending property, mechanical properties and the like described above. As one example, a range of approximately 10% by weight to 50% by weight based on the total weight of the thermosetting resin composition is preferred. When the inorganic filler is excessively included, moldability may decline.

Meanwhile, the thermosetting resin composition according to the present invention may further include a reaction initiator for strengthening advantageous effects of the cross-linkable curing agent.

Such a reaction initiator may further accelerate curing of the polyphenylene ether and the cross-linkable curing agent, and may improve properties such as heat resistance of the resin.

Nonlimiting examples of the usable initiator may include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoxyquinone, chloranyl, 2,4,6-tri-t-butylphenoxyl, t-butylperoxyisopropyl monocarbonate, azobisisobutylonitrile and the like, and metal carboxylate salts may be further used additionally.

The content of the reaction initiator may be from approximately 2 parts by weight to 5 parts by weight with respect to 100 parts by weight of the polyphenylene ether, but is not limited thereto.

In addition, the thermosetting resin composition of the present invention may further include a curing accelerator.

Examples of the curing accelerator may include organic metal salts or organic metal complexes selected from the group consisting iron napthenate, copper napthenate, zinc napthenate, cobalt napthenate, nickel napthenate, manganese napthenate, tin napthenate, zinc octanoate, tin octanoate, iron octanoate, copper octanoate, zinc 2-ethyl hexanate, lead acetylacetonate, cobalt acetylacetonate, dibutyltin maleate and the like, but are not limited thereto. In addition, these may be used as either one type, or as a mixture of two or more types.

The content of the curing accelerator may be in a range of approximately 0.01 parts by weight to 1 parts by weight with respect to 10 parts by weight to 60 parts by weight of the polyphenylene ether, but is not limited thereto.

In addition to the components described above, the thermosetting resin composition of the present invention may additionally include, as long as it does not harm unique properties of the resin composition, a flame retardant generally known in the art, various polymers such as other thermosetting resins that are not described above or thermoplastic resins and oligomers thereof, solid rubber particles, or other additives such as an ultraviolet absorber, an antioxidant, a polymerization initiator, a dye, a pigment, a dispersant, a viscosity agent and a leveling agent as necessary. As one example, an organic filler such as silicone-based powder, nylon powder and fluorine resin powder, a viscosity agent such as Orbene and bentone; a polymer-based antifoamer or leveling agent such as a silicone-based and a fluorine resin-based; a tackifier such as an imidazole-based, a thiazole-based, a triazole-based and a silane-based coupling agent; a colorant such as phthalocyanine and carbon black, and the like, may be included.

According to one example of the present invention, the thermosetting resin composition may include, based on 100 parts by weight of the composition, (a) the polyphenylene ether resin having two or more unsaturated substituents on both ends of the molecular chain in approximately 20 parts by weight to 50 parts by weight; (b) the three or more types of cross-linkable curing agents in approximately 5 parts by weight to 45 parts by weight; and (c) the flame retardant in approximately 10 parts by weight to 30 parts by weight range, and may further include an organic solvent or other components to satisfy a total of 100 parts by weight. Herein, the components may be based on the total weight of the composition, or the total weight of the varnish including the organic solvent.

In the present invention, common organic solvents known in the art may be used as the usable organic solvent without limit, and one example thereof may include acetone, cyclohexanone, methyl ethyl ketone, toluene, xylene, tetrahydrofuran and the like, and these may be used either alone or as a mixture of two or more types.

The content of the organic solvent may be in a residual quantity satisfying the total of 100 parts by weight of the varnish using the composition ratio of the compositions described above, and is not particularly limited.

In the present invention, in order to increase chemical adhesion strength between the copper foil and such a resin layer, any one surface of the copper foil on which the resin layer is to be laminated may be treated with a silane coupling agent. In the present invention, the silane coupling agent is not particularly limited as long as it is an inorganic filler known in the art.

In the present invention, when treating a surface of the copper foil through such a process, it is preferable to carry out flushing between a prior process and a posterior process so that the liquid electrolyte of the prior process and the posterior process are not mixed.

In the present invention, the structure of the copper-clad laminate is not particularly limited, and the copper-clad laminate is formed in various structures having a form binding the copper foil and the resin layer as a base.

Still another embodiment of the present invention relates to a printed circuit board including the copper-clad laminate according to the present invention.

In the present invention, the printed circuit board refers to a printed circuit board laminating one or more layers using a plating through hole method or a build-up method, and may be obtained by stacking and adjusting the above-described prepreg or insulating resin sheet on an inner layer wiring board, and heating and pressing the result.

The printed circuit board may be manufactured using common methods known in the art. As one preferred example thereof, the printed circuit board may be manufactured by laminating a copper foil on one surface or both surfaces of the prepreg according to the present invention, heating and pressing the result to prepare a copper foil laminate, and then carrying out a through hole plating by opening a hole on the copper foil laminate, and forming a circuit through etching the copper foil including the plated film.

Yet another embodiment of the present invention relates to an electronic device including the printed circuit board according to the present invention.

Hereinafter, the present invention will be described in more detail with reference to examples. However, the following examples are just preferred examples of the present invention, and the present invention is not limited to the following examples.

### EXAMPLE

### Examples 1 to 23 and Comparative Examples 1 and 2

### Preparation of Copper Foil

An electrolytic copper foil was prepared using a drum made of titanium having surface roughness Ra of 0.25 μm or less, and through electrolytic deposition, the total thickness was made to 5 μm, 9 μm, 12 μm, 18 μm, 35 μm and 45 μm. After that, a liquid electrolyte having a composition of the following Table 1 was prepared, and roughening (plating) was carried out

Meanwhile, the copper foils having the roughness of the matte sides belonged to the range of the present invention are expressed as Examples 1-23. However, the copper foils of which the roughness of the matte sides were lower than the range of the present invention, are expressed as Comparative Examples 1 and 2.

Liquid Electrolyte Composition

| Copper | Acid | Current Density | Temperature |
|---|---|---|---|
| 20 g/L | 60 g/L | 30 A/dm² | 20° C. |

### Comparative Examples 3 and 4

### Preparation of Commercial Copper Foils

In order to compare roughness and adhesion strength with them of the copper foil of the present invention, commercial copper foils were prepared.

### Preparation Example

### Preparation of Copper Clad Laminate

The copper foils prepared according to Examples 1 to 23 and Comparative Examples 1 to 4 were used. When the thickness of the electrolytic copper foil was less than 35 μm, a copper plated layer having the same composition was formed on a shiny side of the copper foil to make the total thickness 35 μm. A thermosetting resin having a composition of the following Table 2 was laminated on a matte side of the copper foil, and then the result was dried for approximately 3 minutes to 10 minutes at 165° C.

TABLE 2

| Composition | Parts by Weight |
|---|---|
| Allylate PPE | 40 |
| TAIC | 8 |
| 1,2-Butadiene | 8 |
| Di-(4-vinylbenzyl)ether | 2 |
| SBR | 3 |
| Flame Retardant | 9 |
| Initiator | 2 |
| Inorganic filler of Which Surface is | 30 |
| Treated with Vinyl Silane | |
| Vinyl Silane G/F | ∘ |

^{Note}
1) Allylate PPE: MX-9000 (number average molecular weight: 2000 to 3000)
2) 1,2-butadiene: B-1000 (NIPPON SODA)
3) Styrene-butadiene: P-1500 (Asahi Kasei Chemical)
4) TAIC: TAIC (NIPPON KASEI CHEMICAL)
5) Di-(4-vinylbenzyl)ether: BPA-DAE (HAOHUA INDUSTRY)
6) Flame retardant: Saytex 8010 (Albemarle Asano Corporation)
7) Initiator: Perbutyl P (manufactured by NOF Corporation)
8) Inorganic filler: SC-5200SQ (manufactured by Admatechs)

### Test Example 1

1. Measurement on Surface Roughness

For the copper foils roughened in the examples, surface roughness was measured using a perthometer Mahr MarSurf M300C (+RD18C).

2. Measurement on Adhesion Strength

Normal peel strength was measured in accordance with IPC-TM-650 using a peel strength tensile tester Instron 5543. However, the normal peel strength of 0.6 N/mm or greater was employed as being usable in laminate applications.

Results of measuring surface roughness for each of the copper foils and adhesion strength for each of the copper clad laminates as above are as shown in the following Table 3.

TABLE 3

| | | Matte | Shiny | | |
|---|---|---|---|---|---|
| | | side | side | Ratio of the | |
| | Thick- | Mean | Mean | roughness | |
| | ness | Rz JIS | Rz JIS | (Shiny side/ | Adhesion |
| Category | (μm) | (μm) | (μm) | Matte side) | (N/mm) |
| Example 1 | 9 | 1.08 | 1.11 | 1.02 | 0.61 |
| Example 2 | | 1.25 | 1.34 | 1.07 | 0.69 |
| Example 3 | | 1.07 | 1.39 | 1.29 | 0.61 |
| Example 4 | | 1.17 | 1.51 | 1.29 | 0.62 |
| Example 5 | 12 | 1.07 | 1.16 | 1.08 | 0.66 |
| Example 6 | | 1.04 | 1.17 | 1.12 | 0.61 |
| Example 7 | | 1.03 | 1.24 | 1.21 | 0.61 |
| Example 8 | | 1.05 | 1.29 | 1.23 | 0.63 |
| Example 9 | | 1.01 | 1.46 | 1.33 | 0.60 |
| Example 10 | 18 | 1.03 | 1.11 | 1.08 | 0.69 |
| Example 11 | | 0.91 | 1.05 | 1.16 | 0.60 |
| Example 12 | | 1.01 | 1.22 | 1.21 | 0.67 |
| Example 13 | | 1.00 | 1.30 | 1.30 | 0.64 |
| Example 14 | | 0.94 | 1.30 | 1.41 | 0.63 |
| Example 15 | | 0.89 | 1.68 | 1.88 | 0.61 |
| Example 16 | 35 | 1.00 | 1.12 | 1.12 | 0.65 |
| Example 17 | | 0.95 | 1.14 | 1.20 | 0.72 |
| Example 18 | | 0.85 | 1.05 | 1.23 | 0.74 |
| Example 19 | | 1.00 | 1.39 | 1.39 | 0.72 |
| Example 20 | | 0.81 | 1.27 | 1.57 | 0.73 |
| Example 21 | | 0.74 | 1.22 | 1.65 | 0.73 |
| Example 22 | | 0.85 | 1.45 | 1.71 | 0.71 |
| Example 23 | | 0.77 | 1.39 | 1.80 | 0.75 |
| Comparative | 18 | 0.77 | 1.21 | 1.57 | 0.45 |
| Example 1 | | | | | |
| Comparative | 35 | 0.64 | 1.07 | 1.67 | 0.43 |
| Example 2 | | | | | |
| Comparative | 18 | 1.35 | 1.18 | 0.87 | 0.80 |
| Example 3 | | | | | |
| Comparative | 35 | 1.41 | 1.35 | 0.96 | 0.79 |
| Example 4 | | | | | |

As shown in Table 3, it was seen that the mean roughness Rz JIS of the roughened matte side of the copper foil of the present invention (Examples 1 to 23) was from 0.5 μm to 2.0 μm, and it was lower than that of the shiny side. The ratio of the roughness Rz JIS of the shiny side with respect to that of the shiny side was greater than 1 and less than or equal to 2. In addition, the adhesion between the copper foil of the present invention and the resin which was deposited thereon was very superior, it was greater than 0.6N/mm. Furthermore, the copper foil of the present invention exhibited excellent electrical properties (e.g. low insertion loss), although it was not shown in the above Table 3.

However, when the mean roughness Rz JIS of the roughened matte side was less than the range of the present invention (Comparative Examples 1-2), adhesion strength was seen to significantly decrease.

Meanwhile, the mean roughness Rz JIS of the roughened matte side of the commercial copper foil (Comparative Examples 3-4) was greater than that of the shiny side. As a result, the copper foil exhibited very poor electrical properties, although adhesion strength between the commercial copper foil and the resin was superior.

As described above, by adjusting the thickness of the copper foil to a specific range and limiting the profilometer-measured surface roughness to a specific level in the present invention, adhesion between the copper foil and the resin may increase, and an electrical property may be improved as well.

### Test Example 2

On each of the surface treated copper foils of Examples 15 and 23, the thermosetting resin composition of Table 2 was laminated, and the result was dried for approximately 3 minutes to 10 minutes at 165° C. After that, for the resin layer-formed copper foil, floating was carried out at Solder 288° C. in accordance with the IPC TM-650 2.4.13 evaluation rule, and the time taken until separation between the resin layer and the copper foil was measured and evaluated. The results are shown in the following Table 4.

TABLE 4

| Category | Example 15 | Example 23 |
|---|---|---|
| Heat Resistance | >10 min | >10 min |
| (S/F, (@288° C.) | | |

As shown in Table 4, it was identified that excellent heat resistance was exhibited when the composition according to the present invention was coated on the surface treated copper foil according to the present invention.

The copper foil provided in the present invention has excellent adhesion with a resin while having very low roughness of the matte side through roughening.

1. A copper foil having a low roughness property by roughening a matte side of the copper foil,
wherein a thickness of the copper foil is from 5 μm to 70 μm; and
a profilometer-measured mean roughness Rz JIS of the roughened matte side of the copper foil is from 0.5 μm to 2.0 μm,
wherein profilometer-measured mean roughness Rz JIS of the roughened matte side of the copper foil is lower than that of a shiny side of the copper foil.

2. The copper foil of claim 1, wherein the thickness of the copper foil is from 5 μm to 15 μm, and the profilometer-measured mean roughness Rz JIS of the roughened matte side of the copper foil is from 0.8 μm to 1.5 μm.

3. The copper foil of claim 1, wherein the thickness of the copper foil is greater than 15 μm and less than or equal to 30 μm, and the profilometer-measured mean roughness Rz JIS of the roughened matte side of the copper foil is from 0.8 μm to 1.1 μm.

4. The copper foil of claim 1, wherein the thickness of the copper foil is greater than 30 μm and less than or equal to 70 μm, and the profilometer-measured mean roughness Rz JIS of the roughened matte side of the copper foil is from 0.7 μm to 1.0 μm.

5. The copper foil of claim 1, wherein a profilometer-measured maximum roughness Rz JIS of the roughened matte side of the copper foil is from 1.0 μm to 2.0 μm.

6. The copper foil of claim 1, a ratio of the profilometer-measured mean roughness of the shiny side with respect to that of the roughened matte side is greater than 1 and less than or equal to 2.

7. The copper foil of claim 1, wherein particle sizes of roughened particles of the roughened surface of the copper foil are from 0.1 μm to 2.0 μm.

8. The copper foil of claim 7, wherein a height of a projection formed with the roughened particles of the roughened surface of the copper foil is from 1.0 μm to 5.0 μm.

9. The copper foil of claim 1, wherein the copper foil is an electrolytic copper foil.

10. A copper-clad laminate comprising:
the copper foil of claim 1; and
a resin layer laminated on at least one surface of the copper foil.

11. A printed circuit board comprising the copper-clad laminate of claim 10.
